(19) United States
(12) Patent Application Publication
(10) Pub. No.: US 2017/0094779 A1
(43) Pub. Date: Mar. 30, 2017

(54) DRIVE CIRCUIT UNIT AND DISPLAY DEVICE HAVING THE SAME

(71) Applicant: Samsung Display Co., Ltd., Yongin-Si (KR)

(72) Inventors: Jeonghun GO, Asan-si (KR); Ung CHOI, Asan-si (KR); Seonghyun GO, Yongin-si (KR)

(21) Appl. No.: 15/147,227

(22) Filed: May 5, 2016

(30) Foreign Application Priority Data
Sep. 30, 2015 (KR) 10-2015-0138121

(51) Int. Cl. H05K 1/02; G09G 3/20; H05K 1/18

(52) U.S. Cl. CPC H05K 1/0216; H05K 1/181; H05K 1/0201; G09G 3/2092; H05K 2201/10371; H05K 2201/10128; G09G 2300/0426; G09G 2310/027

(57) ABSTRACT

A drive circuit unit includes: a printed circuit board; an electronic device disposed on the printed circuit board; and a shield can disposed on the printed circuit board to surround the electronic device such that an electromagnetic wave generated in the electronic device is shielded, and the shield can further includes a shield cover which overlaps at least a portion of a heat ventilation hole defined in a wall of the shield can in a vertical direction.

This application claims priority to Korean Patent Application No. 10-2015-0138121, filed on Sep. 30, 2015, and all the benefits accruing therefrom under 35 U.S.C. §119, the content of which in its entirety is herein incorporated by reference.

### BACKGROUND

1. Field

The disclosure herein relates to a drive circuit unit and a display device including the drive circuit unit, and more particularly, to a drive circuit unit with improved electromagnetic wave shielding characteristic and a display device including the drive circuit unit.

2. Description of the Related Art

A variety of display devices such as a television (“TV”), a mobile, a navigation, a computer monitor, and a game device for providing multimedia have been developed.

Such display devices typically include a display panel for displaying an image and a control unit that generates various signals for driving the display panel. The control unit may be implemented by various circuits and electronic elements on a printed circuit board.

As the size and resolution of display panels have increased, data amount to be processed by the control unit has increased, and thus an electromagnetic wave generated in the control unit has also increased. A shield can devised to shield the electromagnetic wave may be disposed on the printed circuit board.

### SUMMARY

The disclosure provides a drive circuit unit with improved electromagnetic wave shielding characteristics and a display device including the drive circuit unit.

According to an embodiment of the inventive concept, a drive circuit unit includes: a printed circuit board; an electronic device mounted on the printed circuit board; and a shield can disposed on the printed circuit board, where the shield can surrounds the electronic device and shields an electromagnetic wave generated from the electronic device, and the shield includes a shield cover overlapping at least a portion of a heat ventilation hole defined in a wall of the shield can in a vertical direction.

In an embodiment, the shield cover may extend from a portion of the wall defining an edge of the heat ventilation hole.

In an embodiment, the shield cover may be inclined in a lower direction towards the printed circuit board.

In an embodiment, the shield cover may be inclined in an upper direction away from the printed circuit board.

In an embodiment, an upper surface of the shield cover may form an angle in a range of 15 degrees to 75 degrees with an upper surface of the wall.

In an embodiment, the shield cover may entirely overlap the heat ventilation hole when viewed from a plan view in a vertical direction.

In an embodiment, the heat ventilation hole may include a first edge and a second edge which is opposite to the first edge, and the shield cover extends in a direction to the second edge from a portion of the upper surface which defines the first edge to overlap the second edge when viewed from the plan view in a vertical direction.

In an embodiment, the heat ventilation hole may include the first edge and the second edge which is opposite to the first edge, and the shield cover may include a first shield cover extending in a direction to the second edge from the portion of the wall which defines the first edge, and a second shield cover extending toward the first edge from the portion of the wall which defines the second edge.

In an embodiment, at least a portion of the second shield cover may overlap the first shield cover when viewed from the plan view in the vertical direction.

In an embodiment, an angle formed by the upper surface of the second shield cover with the upper surface of the wall may be different from an angle formed by the upper surface of the first shield cover with the upper surface of the wall.

In an embodiment, the shield cover may include a plurality of sub-shield covers arranged spaced apart by a predetermined distance from each other when viewed from the plan view in a vertical direction.

In an embodiment, the heat ventilation hole may include: a first edge; and a second edge facing the first edge, and the shield cover may include: a plurality of first sub-shield covers which extend in a direction to the second edge from the portion of the wall which defines the first edge; and a plurality of second sub-shield covers which extend in a direction to the first edge from the portion of the wall defining the second edge.

In an embodiment, the plurality of first shield covers and the plurality of second shield covers may be disposed alternately with each other when viewed from the plan view in a vertical direction.

In an embodiment, the shield can may include an electromagnetic wave shielding material.

In an embodiments of the inventive concept, a display device includes: a display panel; a drive circuit unit connected to the display panel and which drives the display panel, where the drive circuit unit includes: a printed circuit board; an electronic device disposed on the printed circuit board; and a shield can disposed on the printed circuit board, where the shield can surrounds the electronic element to shield electromagnetic wave occurring in the electronic device, where the shield can includes a shield cover overlapping at least a portion of a heat ventilation hole defined in a wall of the shield can when viewed from a plan view in a vertical direction.

In an embodiment, the shield cover may extend from the portion of wall defining an edge of the heat ventilation hole.

In an embodiment, the shield cover may be inclined in a lower direction to the printed circuit board.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view illustrating a drive circuit unit according to an embodiment of the inventive concept;

FIG. 2 is a cross-sectional view taken along line I-I′ in FIG. 1;

FIG. 3 is a graph illustrating a simulation result of an electromagnetic wave shielding characteristic according to a first angle;

FIGS. 4A to 4C are views illustrating a shield cover according to an embodiment of the inventive concept;

FIG. 5 is a plan view illustrating a portion of a shield cover according to an embodiment of the inventive concept;

FIGS. 6A and 6B are views illustrating shield covers according to embodiments of the inventive concept;

FIG. 7 is a plan view illustrating a portion of a shield cover according to an embodiment of the inventive concept; and

FIG. 8 is a plane view of a display device according to an embodiment of the inventive concept.

### DETAILED DESCRIPTION

Although specific embodiments are illustrated in the accompanying drawings and referenced in the specification, the disclosure can be modified in various manners and encompass embodiments not expressly disclosed. The scope of the embodiments of the disclosure are not limited to the specific embodiments and should be construed as including all the changes, equivalents, and substitutions that are within the spirit and scope of the system and method.

Like reference numerals in the drawings denote like elements. In the drawings, the dimensions of structures are exaggerated for clarity. It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the meaning of “include”, “comprise”, “including”, “comprising”, “have”, or “having” specifies a characteristic, a fixed number, a step, a process, an element, a component and/or a combination thereof, but does not exclude other properties, fixed numbers, steps, processes, elements, components and/or combinations thereof. It will also be understood that when a layer, a film, a region, or a substrate is referred to as being “on” another one, it can be directly on the other one, or one or more intervening ones may also be present. To the contrary, when a layer, a film, a region, or a substrate is referred to as being “under” another one, it can be directly under the other one, or one or more intervening ones may also be present.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the inventive concept will be described in detail with reference to the accompanying drawings.

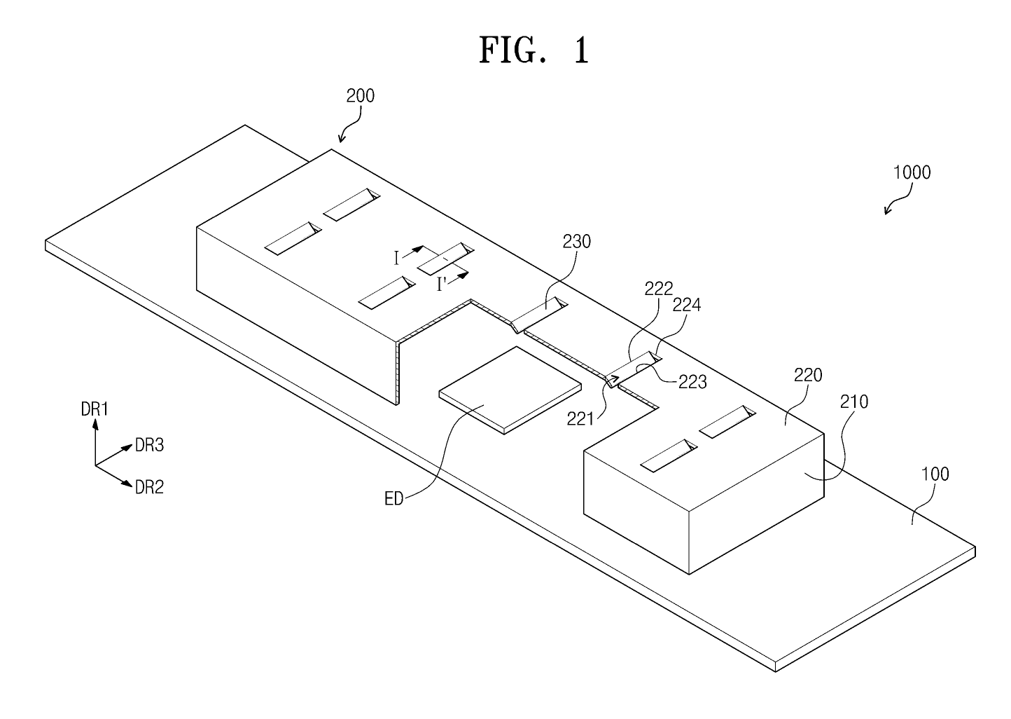

FIG. 1 is a perspective view illustrating a drive circuit unit according to an embodiment of the inventive concept.

Referring to FIG. 1, an embodiment of a drive circuit unit 1000 includes a printed circuit board 100 and a shield can 200.

In such an embodiment, at least one of a variety of electronic devices ED, which define or constitute a control unit for driving an electronic apparatus or a processing unit such as an arithmetic unit or the like, may be disposed or mounted on the printed circuit board 100. In one embodiment, for example, the printed circuit board 100 may include a capacitor and a resistor, or a microprocessor including an integrated circuit a memory chip and interconnection lines which connect such elements.

The shield can 200 is disposed on the printed circuit board 100. In FIG. 1, the shield can 200 is partially cut away for illustrative purpose and for convenience of explanation. The shield can 200 includes, for example, a plurality of side walls 210 which extend in a direction (hereinafter, referred to as a vertical direction or a first direction DR1) substantially vertical to the printed circuit board 100, and a top wall 220 which is connected to extended ends of the plurality of side walls 210 and is parallel to the printed circuit board 100. Herein, the top wall 200 may be a wall in the first direction DR1 or facing the first direction DR1.

In an embodiment of the inventive concept, when viewed from a plane in the first direction or a thickness direction of the printed circuit board 100, the top wall 220 may have a rectangular shape having a pair of long sides parallel to each other and a pair of short sides parallel to each other. In one embodiment, for example, the long sides are parallel to a second direction DR2, and the short sides may be parallel to a third direction DR3. In an embodiment of the inventive concept, the first to third directions DR1 to DR3 may be orthogonal to one another.

The shield can 200 may include an electromagnetic wave shielding substance or material which reflects or absorbs electromagnetic waves. In one embodiment, for example, the electromagnetic wave shielding substance or material may include aluminum, copper, iron, a mixture thereof, or a compound thereof.

In an embodiment, the shield can 200 is configured to surround an electronic device ED on a predetermined area of the printed circuit board 100 to shield electromagnetic waves occurring from the electronic device ED. In such an embodiment, the shield can 200 may shield electromagnetic waves incident from the outside, thereby protecting the electronic device ED from the electromagnetic waves incident from the outside of the shield can 200.

A heat ventilation hole 221 may be defined in the top wall 220. In an embodiment of the inventive concept, the heat ventilation hole 221 may be provided in plural. In one embodiment, for example, the plurality of heat ventilation holes 221 may be arranged in a matrix form in which 10 heat ventilation holes are arranged in 2 rows and 5 columns. Each of the plurality of heat ventilation holes 221 may be formed by opening a corresponding portion of the top wall 220 when viewed from a plan view in the first direction DR1.

In an embodiment of the inventive concept, when viewed from a plan view, each of the plurality of heat ventilation holes 221 may have a substantially rectangular shape. Each of the plurality of heat ventilation holes 221 includes first and second edges 222 and 223. The first and the second edges 222 and 223 are parallel to the third direction DR3, and are spaced apart from each other in the second direction DR2 to be opposed to each other. The first and second edges 222 and 223 may be defined as long sides of each of the plurality of heat ventilation holes 221. In such an embodiment, each of the plurality of heat ventilation holes 221 includes a third edge 224. The third edge 224 may be parallel to the third direction DR3 and define a short side of each of the plurality of heat ventilation holes 221. Lengths of the long and short sides of the heat ventilation hole 221 may be, for example, about 1 millimeter to about 100 millimeters.

In an embodiment of the inventive concept, the shape of the plurality of heat ventilation holes 221 when viewed from the top plan view is not limited to a rectangular shape, but may be modified into various shapes such as a circular, oval, non-rectangular polygonal shape or the like.

Heat generated in the electronic device ED may be discharged to the outside of the shield can 200 through the heat ventilation holes 221. Thus, the temperature inside the shield can 200 and the temperature of the electronic device ED surrounded by the shield can 200 may be effectively prevented from rising by the heat generated in the electronic device ED.

The shield can 200 includes a shield cover 230. According to an embodiment of the inventive concept, the shield cover 230 may be provided in plurality, and may be arranged to respectively correspond to the plurality of heat ventilation holes 221. Each of the plurality of shield covers 230 may overlap at least a portion of the corresponding heat ventilation hole 221 when viewed from a plan view in the first direction DR1.

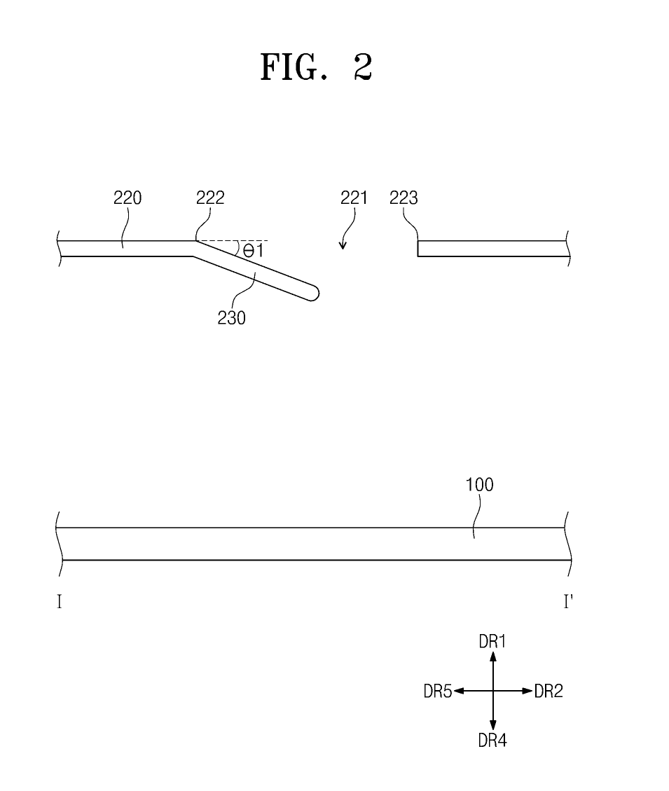

FIG. 2 is a cross-sectional view of the drive circuit unit taken along line I-I′ illustrated in FIG. 1.

In such an embodiment, the plurality of heat ventilation holes 221 and shield covers 230 corresponding thereto are substantially the same as each other. For convenience of illustration, only one heat ventilation hole 221 and one shield cover 230 corresponding thereto are illustrated in FIG. 2 from among the plurality of heat ventilation holes 221 and shield covers 230 illustrated in FIG. 1, and the detailed description of the remaining heat ventilation holes and the remaining shield covers will be omitted.

As illustrated in FIG. 2, according to an embodiment of the inventive concept, the shield cover 230 may be branched from a portion of the top wall 220, which defines the first edge 222 and extend toward the second edge 223. In such an embodiment, the shield cover 230 has an end which extends in the second direction DR2.

According to an embodiment of the inventive concept, the shield cover 230 may be inclined toward the printed circuit board 100. In such an embodiment, the shield cover 230 may have an end that slantingly extends in a fourth direction DR4 opposite to the first direction DR1.

According to an embodiment of the inventive concept, the shield cover 230 may overlap at least a portion of the heat ventilation hole 221 when viewed from a plan view in the first direction DR1. In one embodiment, for example, as illustrated in FIG. 2, the shield cover 230 may be disposed to overlap an area corresponding to half of the total area of the heat ventilation hole 221 when viewed from a plan view in the first direction DR1. According to an embodiment of the inventive concept, an end of the shield cover 230 may not overlap the second edge 223 when viewed from a plan view in the first direction DR1.

In an embodiment of the inventive concept, an upper surface of the shield cover 230 may form a first angle θ1 with an upper surface of the top wall 220. According to an embodiment of the inventive concept, the first angle θ1 may be in a range of about 15 degrees to about 75 degrees.

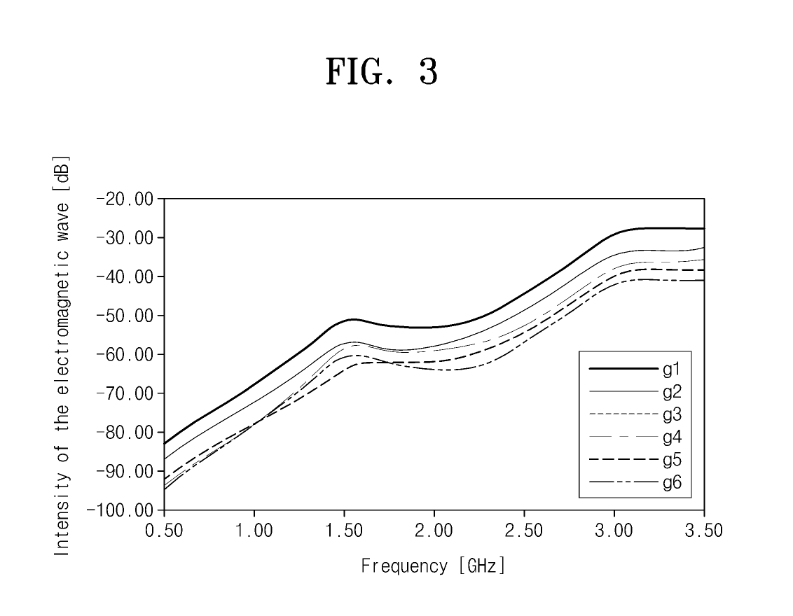

FIG. 3 is a graph illustrating a simulation result of an electromagnetic wave shielding characteristic according to the first angle.

In the graph of FIG. 3, the x-axis represents the frequency (unit: gigahertz (GHz)) of an electrowave, and the y-axis represents the intensity (unit: decibel (dB)) of the electromagnetic wave (H-field). A first graph g1 represents the intensity of the radiated electromagnetic radiation according to the frequency in a comparative embodiment where a reference shield can is not provided with the shield cover 230. Second to sixth graphs g2 to g6 represent the intensity of the radiated electromagnetic wave according to the frequency in embodiments where shield cans provided with the shield cover 230 in which the first angle θ1 is 76, 60, 45, 30 and 15 degrees, respectively, are provided. In the graphs of FIG. 3, as the intensity of the radiated electromagnetic wave decreases, the electromagnetic wave shielding characteristic of the shield can may be improved. The lengths of the long and short sides of the heat ventilation hole 221 are about 8 millimeters and about 1 millimeter respectively. A HFSS simulation tool of ANSYS, Inc. which uses a 3D Finite Element Method (“3D FEM”) analysis technique is used for the simulation.

As illustrated in FIG. 3, in all frequency bands, the second to sixth graphs g2 to g6 have smaller electromagnetic wave intensities than the first graph g1. The intensity of the electromagnetic wave in the sixth graph g6 is smallest in the frequency band around 2 GHz, and the intensity of the electromagnetic wave in the fifth graph g5 is smallest in the frequency band around 1.5 GHz. The first angle θ1 may be determined to correspond to the frequency of the electromagnetic wave to be shielded by the shield can 200.

As shown in FIG. 3, the electromagnetic wave shielding characteristic of the shield can 200 may be improved in an embodiment, where the shield cover 230, which covers at least a portion of the heat ventilation hole 221, is provided in the shield can 200. Thus, the electronic device ED covered by the shield can 200 is improved in operating reliability, so that the electronic apparatus including the electronic device ED may be stably driven.

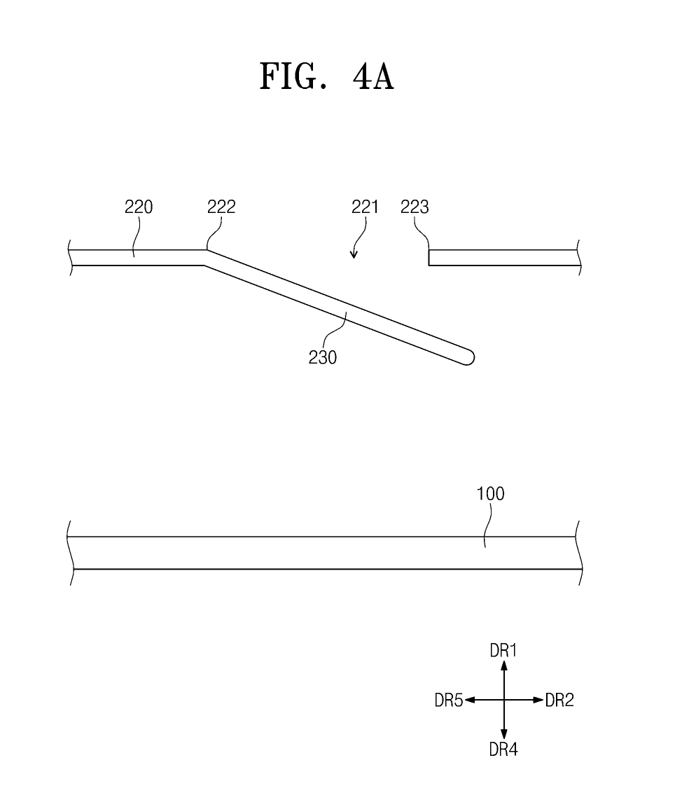

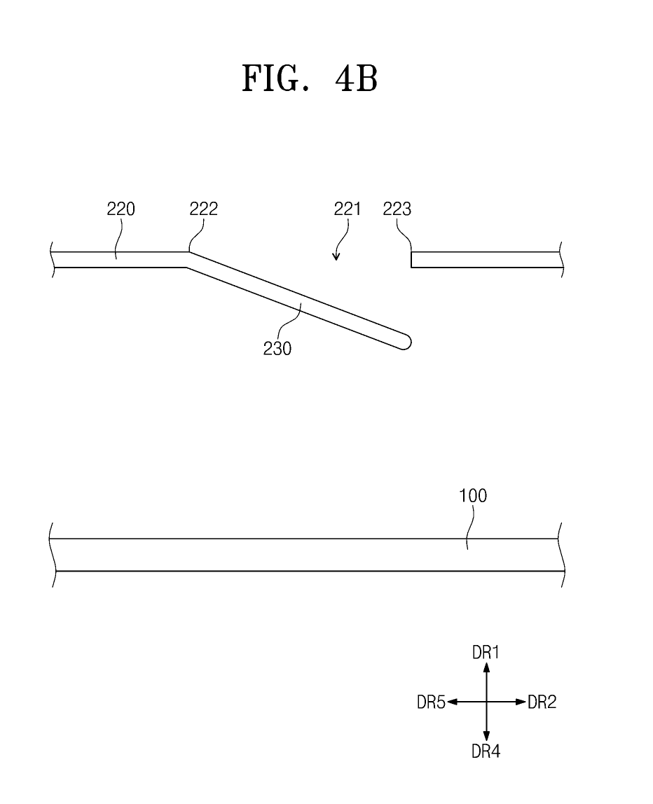

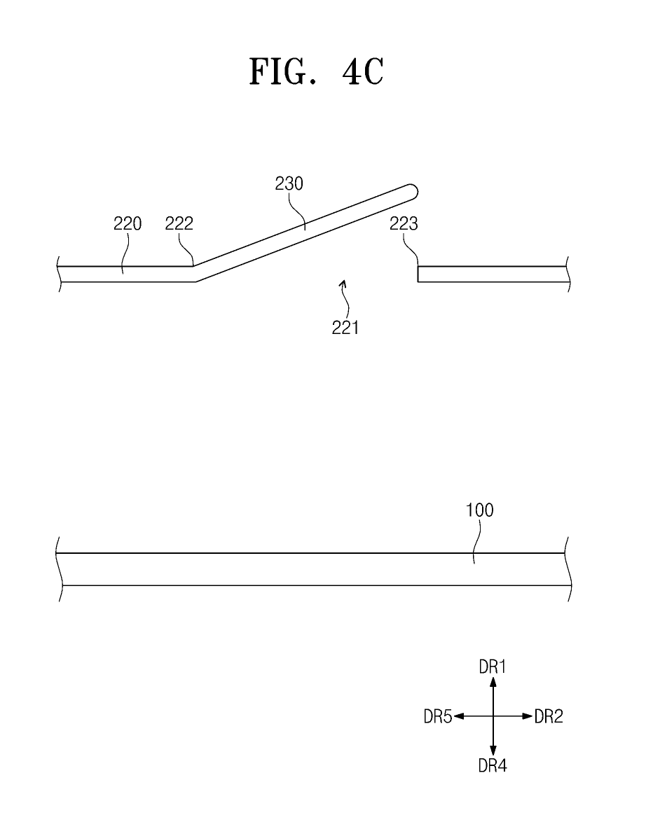

FIGS. 4A to 4C are views illustrating a shield cover according to an embodiment of the inventive concept.

Referring to FIG. 4A, in an embodiment, an end of a shield cover 230 may extend in a second direction DR2 to overlap a second edge 223 when viewed from a plan view in a first direction DR1. In an alternative embodiment, as illustrated in FIG. 4B, the shield cover 230 may substantially entirely overlap a heat ventilation hole 221 when viewed from a plan view in a first direction DR1. Herein, “two or more constituents substantially entirely overlap” may refer to a case in which the corresponding constituents are provided to have substantially the same area in substantially the same plane area. Also, “two constituents substantially entirely overlap” may include a case in which some portion of two layers does not overlap with each other, or the two layers overlap with each other at least 80% of the entire area due to an error in a manufacturing process.

According to another alternative embodiment of the inventive concept, as illustrated in FIG. 4C, the shield cover 230 may slantingly extend in a direction away from the printed circuit board 100. In such an embodiment, the shield cover 230 may have an end that slantingly extends in the first direction DR1.

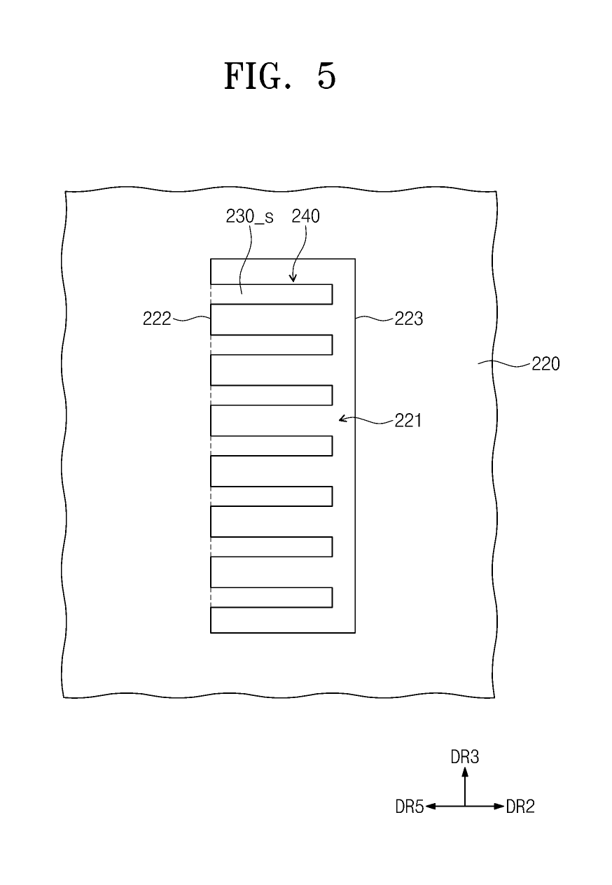

FIG. 5 is a plan view illustrating a portion of a shield cover according to an embodiment of the inventive concept.

Referring to FIG. 5, in an embodiment, a shield cover 240 includes a plurality of sub-shield covers 230_s.

According to an embodiment of the inventive concept, the plurality of sub-shield covers 230_s are arranged along a third direction DR3, and each of the plurality of sub-shield covers 230_s may slantingly extend in the second direction DR2 from the first edge 222. The plurality of sub-shield covers 230_s may be spaced apart by a predetermined distance from each other in the third direction DR3.

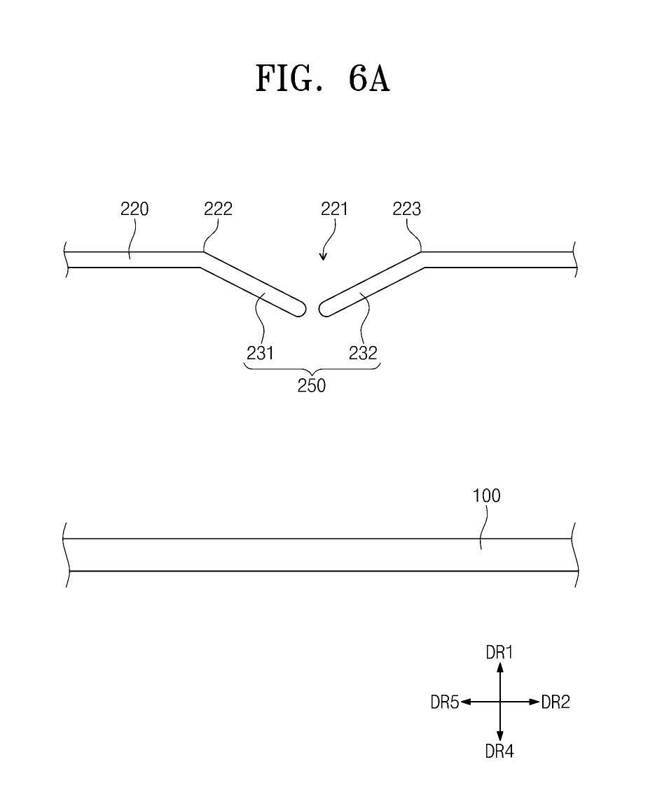

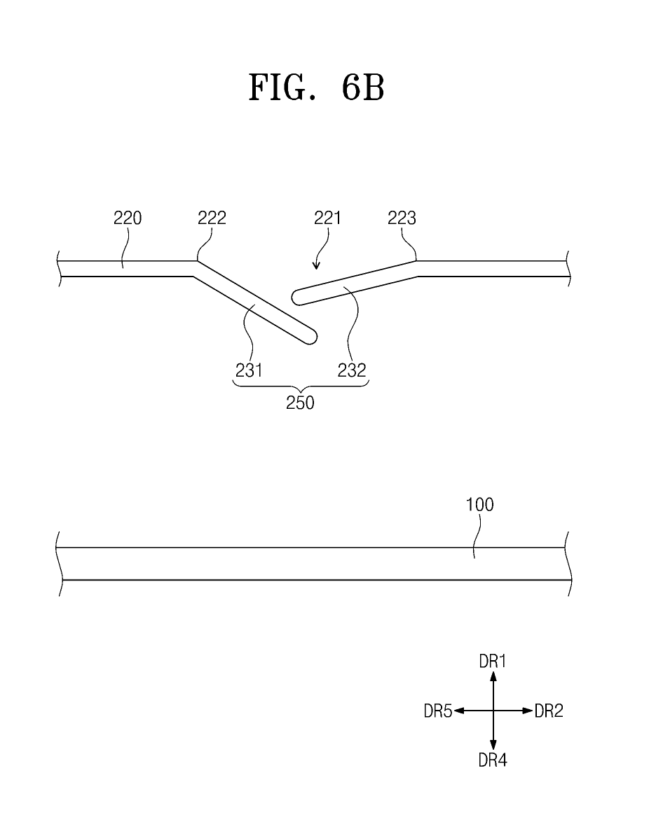

FIGS. 6A and 6B are views illustrating shield covers according to embodiments of the inventive concept.

Referring to FIG. 6A, in an embodiment, the shield cover 250 may include first and second shield covers 231 and 232.

The first shield cover 231 is extending from the first edge 222 in the second direction DR2 and inclined downward, and the second shield cover 232 is extending from the second edge 223 in a fifth direction DES opposite to the second direction DR2 and inclined downward.

According to an embodiment of the inventive concept, an angle which an upper surface of the first shield cover 231 forms with an upper surface of the top wall 200 may be equal to an angle which an upper surface of the second shield cover 230 forms with the upper surface of the top wall 220. According an embodiment of the inventive concept, the angle which the upper surface of the first shield cover 231 forms with the upper surface of the top wall 200 may be different from the angle which the upper surface of the second shield cover 230 forms with the upper surface of the top wall 220.

According to an embodiment of the inventive concept, the first and second shield covers 231 and 232 may not overlap each other when viewed from a plan view in the first direction DR1.

According to an alternative embodiment of the inventive concept, as illustrated in FIG. 6B, the first and second shield covers 231 and 232 may overlap each other when viewed from a plan view in the first direction DR1. An angle which the upper surface of first shield cover 231 forms with the upper surface of top wall 220 may be greater than an angle which the upper surface of second shield cover 230 forms with the upper surface of top wall 220.

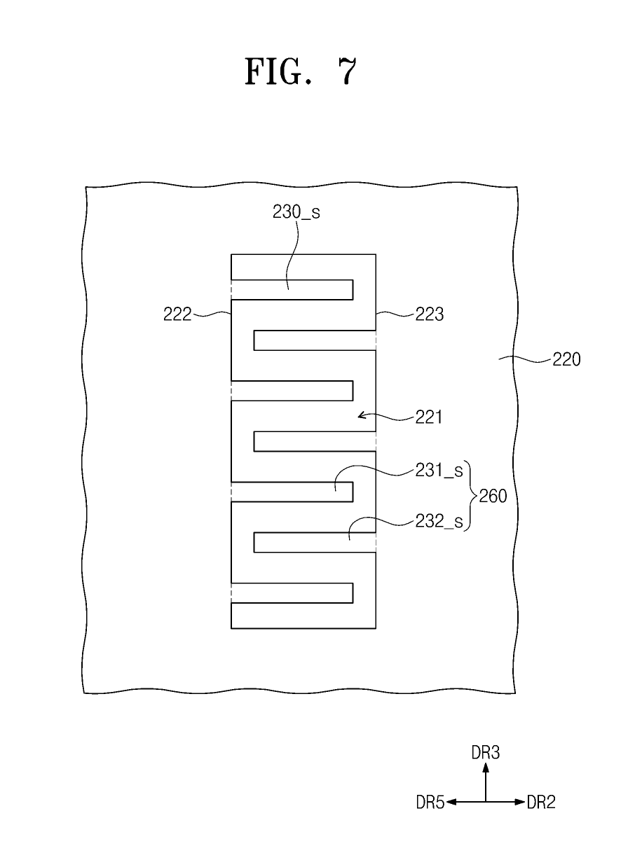

FIG. 7 is a plan view illustrating a portion of a shield cover according to an embodiment of the inventive concept.

Referring to FIG. 7, the shield cover 260 includes a plurality of first sub-shield covers 231_s and a plurality of second sub-shield covers 232_s.

According to an embodiment of the inventive concept, the plurality of first sub-shield covers 231_s is arranged along the third direction DR3. Each of the plurality of first sub-shield covers 231_s may be extending in the second direction DR2 from the first edge 222 and inclined upward or downward. The plurality of first sub-shield covers 231_s may be spaced apart by a predetermined distance from each other in the third direction DR3.

In such an embodiment, each of the plurality of second sub-shield covers 232_s may be extending in the fifth direction DR5 from the second edge 223 and inclined upward or downward. The plurality of second sub-shield covers 232_s may be spaced apart by a predetermined distance from each other in the third direction DR3.

The plurality of first and second sub-shield covers 231_s and 232_s may be disposed alternately with each other along the third direction DR3.

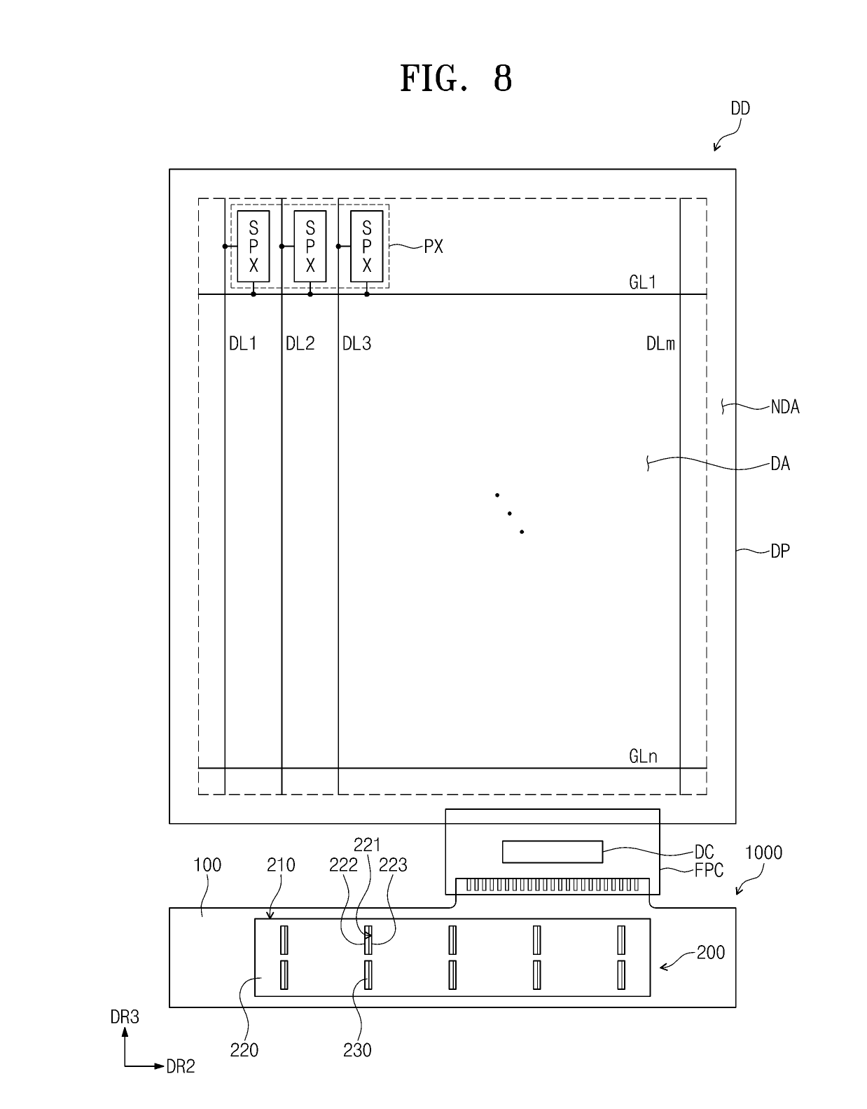

FIG. 8 is a plane view of a display device according to an embodiment of the inventive concept.

Referring to FIG. 8, an embodiment of a display device DD includes a drive circuit unit 1000, a flexible printed circuit board FPC, and a display panel DP.

The display panel DP may display an image through a display area DA. The display area DA may be driven by a control signal and an image data respectively provided from a printed circuit board 100.

The display panel DP includes gate lines GL1 to GLn, data lines DL1 to DLm, and sub-pixels SPX disposed in the display area DA. The gate lines GL1 to GLn, for example, extend along a second direction DR2 to be arranged along the third direction DR3. The data lines DL1 to DLm intersect the gate lines GL1 to GLn to be insulated therefrom. In one embodiment, for example, the data lines DL1 to DLm extend along the third direction DR3, and may be arranged along the second direction DR2. The display panel DP may further include driving lines disposed in a non-display area NDA which surrounds the display area DA. The driving lines may transmit signals for driving the sub-pixels SPX.

Each of the sub-pixels SPX is connected to a corresponding gate line from among the gate lines GL1 to GLn, and to a corresponding data line from among the data lines DL1 to DLm.

The sub-pixels SPX may be arranged in a matrix form along the second and third directions DR2 and DR3. The sub-pixels SPX may display any one of primary colors such as red, green, or blue. However, the inventive concept is not limited thereto, and in an alternative embodiment, the sub-pixels SPX may display a variety of colors such as white or secondary primary colors including yellow, cyan, and magenta in addition to the red, green, and blue colors.

The sub-pixels SPX may constitute a pixel PX. According to an embodiment of the inventive concept, three sub-pixels SPX may constitute one pixel PX. However, the inventive concept is not limited thereto, and in another embodiment, two, four, or more sub-pixels may constitute one pixel PX.

The pixel PX is an element for displaying a unit image, and resolution of the display panel DP may be determined by the number of pixels PX disposed on the display panel DP. For convenience of illustration, only one pixel PX is illustrated in FIG. 8, and the illustration of the remaining pixels is omitted.

The flexible printed circuit board FPC connects the display panel DP and the printed circuit board 100 to each other.

According to an embodiment of the inventive concept, the flexible printed circuit board FPC may include a driver chip DC. The driver chip DC may be disposed or mounted on the flexible printed circuit board FPC, for example, in a tape carrier package (“TCP”) form, and may include a chip in which a data driver (not illustrated) is implemented. The driver chip DC may further include a chip in which a gate driver is implemented.

The printed circuit board 100 may include a control unit (not illustrated). The control unit receives input image signals, converts data format of the input image signals to meet an interface specification and a driving mode of the data driver, and generates the image data. The control unit outputs the image data and the control signal. The image data may include information on an image to be displayed in the display area DA.

The data driver receives the image data and the control signal respectively. The data driver converts the image data into data voltages in response to the control signal, and outputs the data voltages to the data lines DL1 to DLm. The data voltages may be analog voltages corresponding to the image data.

In an embodiment of the inventive concept, the display panel DP may be an organic light emitting display panel, and the sub-pixels SPX may include an organic light emitting element. In an embodiment of the inventive concept, the display panel DP may be a liquid crystal display panel, the sub-pixels SPX may include a liquid crystal layer, and the display device DD may include a backlight unit disposed on the rear side of the display panel DP.

While the disclosure has been particularly shown and described with reference to exemplary embodiments thereof, it will be understood by those skilled in the art that various changes in form and details may be made therein without departing from the spirit and scope of the inventive concept as defined by the appended claims.

Therefore, the scope of the inventive concept should not be limited to the details described herein but should be defined by the following claims.

What is claimed is:

1. A drive circuit unit comprising:
a printed circuit board;
an electronic device disposed on the printed circuit board; and
a shield can disposed on the printed circuit board, wherein the shield can surrounds the electronic device and shields an electromagnetic wave generated from the electronic device,
wherein the shield can comprises a shield cover which overlaps at least a portion of a heat ventilation hole defined in a wall of the shield can in a vertical direction.

2. The drive circuit unit of claim 1, wherein the shield cover extends from a portion of the wall defining an edge of the heat ventilation hole.

3. The drive circuit unit of claim 2, wherein the shield cover is inclined in a downward direction towards the printed circuit board.

4. The drive circuit unit of claim 2, wherein the shield cover is inclined in an upward direction away from the printed circuit board.

5. The drive circuit unit of claim 1, wherein an upper surface of the shield cover forms an angle in a range of about 15 degrees to about 75 degrees with an upper surface of the wall.

6. The drive circuit unit of claim 1, wherein the shield cover entirely overlaps the heat ventilation hole when viewed from a plan view in the vertical direction.

7. The drive circuit unit of claim 1, wherein
the heat ventilation hole comprises a first edge and a second edge opposed to the first edge, and
the shield cover extends toward the second edge from a portion of the wall defining the first edge to overlap the second edge when viewed from a plan view in the vertical direction.

8. The drive circuit unit of claim 1, wherein
the heat ventilation hole comprises a first edge and a second edge opposed to the first edge,
the shield cover comprises:
a first shield cover extending toward the second edge from a portion of the wall defining the first edge; and
a second shield cover extending toward the first edge from a portion of the wall defining the second edge.

9. The drive circuit unit of claim 8, wherein at least a portion of the second shield cover overlaps the first shield cover when viewed from a plan view in the vertical direction.

10. The drive circuit unit of claim 8, wherein an angle formed by an upper surface of the second shield cover with an upper surface of the wall is different from an angle formed by an upper surface of the first shield cover with the upper surface of the wall.

11. The drive circuit unit of claim 1, wherein the shield cover comprises a plurality of sub-shield covers disposed spaced apart by a predetermined distance from each other when viewed from a plan view in the vertical direction.

12. The drive circuit unit of claim 1, wherein
the heat ventilation hole comprises a first edge and a second edge opposed to the first edge, and
the shield cover comprises:
a plurality of first sub-shield covers which extends toward the second edge from a portion of the wall defining the first edge; and
a plurality of second sub-shield covers which extends toward the first edge from a portion of the wall defining the second edge.

13. The drive circuit unit of claim 12, wherein the plurality of first and second shield covers is disposed alternately with each other when viewed from a plan view in the vertical direction.

14. The drive circuit unit of claim 1, wherein the shield can comprises an electromagnetic wave shielding material.

15. A display device comprising:
a display panel; and
a drive circuit unit connected to the display panel and which drives the display panel;
wherein the drive circuit unit comprises:
a printed circuit board;
an electronic device disposed on the printed circuit board; and
a shield can disposed on the printed circuit board, wherein the shield can surrounds the electronic device and shields an electromagnetic wave generated from the electronic device;
wherein the shield can comprises a shield cover overlapping at least a portion of a heat ventilation hole defined in a wall of the shield can in a vertical direction.

16. The display device of claim 15, wherein the shield cover extends from a portion of the wall defining an edge of the heat ventilation hole.

17. The display device of claim 16, wherein the shield cover is inclined in a downward direction towards the printed circuit board.
